(19) United States
(12) Patent Application Publication
(10) Pub. No.: US 2020/0203358 A1
(43) Pub. Date: Jun. 25, 2020

(54) FERROELECTRICS USING THIN ALLOY OF PARA-ELECTRIC MATERIALS

(71) Applicant: Intel Corporation, Santa Clara, CA (US)

(72) Inventors: Uygar E. Avci, Portland, OR (US); Joshua M. Howard, Portland, OR (US); Seiyon Kim, Portland, OR (US); Ian A. Young, Portland, OR (US)

(73) Assignee: Intel Corporation, Santa Clara, CA (US)

(21) Appl. No.: 16/642,358

(22) PCT Filed: Sep. 27, 2017
(86) PCT No.: PCT/US2017/053838

§ 371 Date: Feb. 26, 2020

(51) Int. Cl. H01L 27/11507; H01L 23/528; H01L 23/522; H01L 27/1159; H01L 49/02; H01L 29/78; H01L 29/51

(52) U.S. Cl. CPC H01L 27/11507; H01L 23/528; H01L 23/5226; H01L 29/517; H01L 28/60; H01L 29/78391; H01L 29/516; H01L 27/1159

(57) ABSTRACT

Described is an apparatus which comprises: a first layer comprising a metal; a second layer comprising a first para-electric material, the second layer adjacent to the first layer; and a third layer comprising a second para-electric material, the third layer adjacent to the second layer, wherein the first para-electric material is different from the second para-electric material.

### BACKGROUND

Ferroelectric (FE) materials (such as Barium Strontium Titanate (BST), lead zirconate titanate (PST), lead titanate (PbTiO₃), lead lanthanaum zirconate titanate (PLZT), etc.) have been investigated for non-volatile logic applications such as embedded ultra-low power applications, energy scavenging systems, internet of things (IOT), etc. These FE materials exhibit FE properties from the onset, such as spontaneous electric polarization that can be reversed by application of an electric field.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-section of a backend stack having a FE capacitor (FE-Cap) comprising alloy of para-electric materials, according to some embodiments of the disclosure.

FIG. 2 illustrates a cross-section of an FE-cap comprising an alloy of para-electric materials with same thicknesses, according to some embodiments of the disclosure.

FIG. 3 illustrates a cross-section of an FE-cap comprising an alloy of para-electric materials with different thicknesses, according to some embodiments of the disclosure.

FIG. 4 illustrates an apparatus showing a top down view of distributed metal-insulator-metal (MIM) capacitors comprising FE-caps formed by alloys of para-electric materials, according to some embodiments of the disclosure.

FIG. 5A illustrates a schematic of an FE-Cap comprising an alloy of para-electric materials, according to some embodiments of the disclosure.

FIG. 5B illustrates a plot showing charge versus voltage function of the FE-Cap comprising an alloy of para-electric materials, and its memory states, according to some embodiments of the disclosure.

FIG. 6 illustrates a cross-section of an FE stack formed on a semiconductor, the FE stack comprising an alloy of para-electric materials with same thicknesses, according to some embodiments of the disclosure.

FIG. 7 illustrates a cross-section of an FE stack formed on a semiconductor, the FE stack comprising an alloy of para-electric materials with different thicknesses, according to some embodiments of the disclosure.

FIGS. 8A-B illustrate a 3D view of FE field effect transistor (FET) comprising an alloy of para-electric materials, in accordance with some embodiments of the disclosure.

FIGS. 9A-B illustrate an apparatus for switch mode power supply during charging and discharging modes, respectively, using FE-caps formed of alloys of para-electric materials, according to some embodiments of the disclosure.

FIG. 10 illustrates a 4-terminal controlled switch for the power plane of FIGS. 9A-B, according to some embodiments of the disclosure.

FIG. 11 illustrates a smart device or a computer system or a SoC (System-on-Chip) having an FE-cap comprising an alloy of para-electric materials, according to some embodiments.

### DETAILED DESCRIPTION

Some embodiments describe an enhanced ferroelectric (FE) behavior from an alloy of para-electric materials. Para-electric material generally generates dielectric polarizations (e.g., electronic, ionic, and/or orientational) when an electric field is applied to it. The para-electric material loses this dielectric polarization when the electric field is removed. Overall, a para-electric material has a small permittivity and a small dielectric loss. In some embodiments, the alloy of para-electric materials is an FE material which enables higher remnant polarization, endurance cycles, and retention time. In some embodiments, the materials for the alloy are associated with ferroelectric behavior. These materials can replace transitional dielectric oxides in metal-insulator-metal (MIM) capacitor and metal-ferroelectric-semiconductor structures for various device applications such as embedded dynamic random access memory (eDRAM), non-volatile memory (NVM), etc. In some embodiments, any combination of: HfO₂, ZrO₂, TiO₂, SiO₂, ScO₂, Al₂O₃, ZnO, Sn₂O₄, La₂O₃, silicates, nitrides, etc. In various embodiments, layering the above materials (e.g., monolayers of such materials) introduces large stress between the monolayers. The stress changes the lattice constant of the crystals of the materials such that the stressed crystals tend to behave as orthorhombic and thus ferroelectric. As such, a wide new array of materials can be used to form ferroelectrics. Other technical effects will be evident from the various embodiments and figures.

Some embodiments disclose a backend MIM capacitor comprising an alloy of para-electric materials, and interface materials to enable such capacitors. In some cases, these FE-caps are super capacitors, in accordance with some embodiments. In some embodiments, the FE-caps are switched capacitors. In some embodiments, the backend structures comprising FE-caps enable switch capacitor power supplies for very low voltage generation. Some embodiments describe a patterned FE-cap array formed in an IC (integrated circuit) chip.

In the following description, numerous details are discussed to provide a more thorough explanation of the embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

It is pointed out that those elements of a figure having the same reference numbers (or names) as the elements of any other figure can operate or function in any manner similar to that described, but are not limited to such.

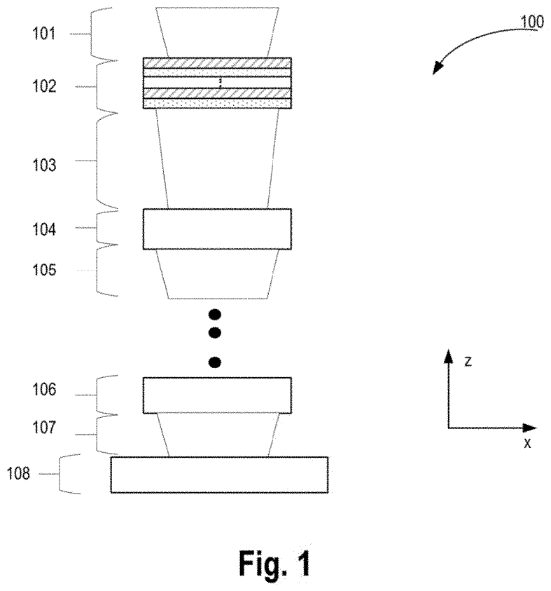

FIG. 1 illustrates a cross-section 100 of a backend stack having an FE capacitor (FE-Cap) comprising an alloy of para-electric materials, according to some embodiments of the disclosure. In some embodiments, a backend stack of layers includes a layer of metal interconnect (e.g., 104, 106, and 108) and vias (e.g., 101, 103, 105, and 107). Here, the term “backend” generally refers to a section of a die which is opposite of a “frontend” and where an IC (integrated circuit) package couples to IC die bumps. For example, high level metal layers (e.g., metal layer 6 and above in a ten metal stack die) and corresponding vias that are closer to a die package are considered part of the backend of the die. In another instance, a region of a die over and including the first metal layer is referred to as the backend region. Conversely, the term “frontend” generally refers to a section of the die that includes the active region (e.g., where transistors are fabricated) and low level metal layers and corresponding vias that are closer to the active region (e.g., metal layer 5 and below in the ten metal stack die example). In another example, a region of a die below the first metal layer is referred to as the frontend region.

In some embodiments, one or more of these interconnect (e.g., 104, 106, and 108) can be parallel to one another or orthogonal to one another, in accordance with some embodiments. In some embodiments, all of these interconnects (e.g., 104, 106, and 108) can be parallel to one another. In some embodiments, FE-Cap 102 can be fabricated between two metal layers, between a metal layer and a via, or between two vias.

In some embodiment, FE-Cap 102 is a super capacitor for charge storage. The term “super capacitor”, “supercapacitor” and “ultracapacitor” are interchangeable terms. A super capacitor can be used for storing large amounts of charge for providing backup power, regeneration braking storage, peak power assist, and other types of charge/discharge functions.

In some embodiments, FE-Cap 102 comprises alternating layers of first and second layers, wherein the first layer comprises a first para-electric material, the first layer adjacent to the second layer, wherein the second layer comprises a second para-electric material, and wherein the first para-electric material is different from the second para-electric material. As such, an alloy of para-electric materials is formed when the para-electric materials are heated, in accordance with some embodiments. In some embodiments, the first and second para-electric materials include one or more of: HfO₂, ZrO₂, TiO₂, SiO₂, ScO₂, Al₂O₃, ZnO, Sn₂O₃, La₂O₃, nitride, or silicate. In some embodiments, the first and second para-electric materials have the same properties, and when these materials are co-mingled with heat, the resultant is an unexpected ferroelectric. In some embodiments, the first and second para-electric materials may not diffuse with one another but stress caused by the first and second para-electric materials to one another change their lattice constants such that the resultant stack of alternating first and second para-electric materials exhibit FE properties.

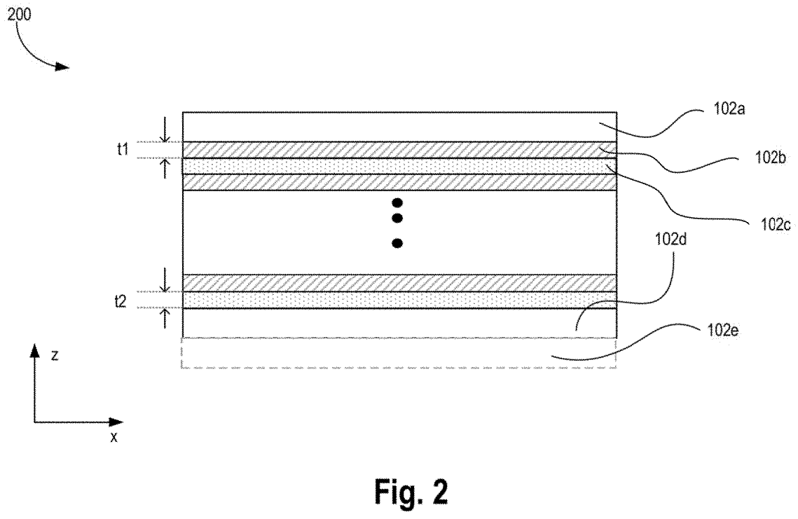

FIG. 2 illustrates a cross-section of an FE-cap 200 (e.g., 102) comprising an alloy of para-electric materials with a same thickness (or substantially the same thickness), according to some embodiments of the disclosure. In some embodiments, capacitor 200 comprises a first conductive layer 102a, and alternating layers of first para-electric material 102b and second para-electric material 102c, and a second conductive layer 102d. In some embodiments, first para-electric material 102b and second para-electric material 102c are alternated at least two times. In other embodiments, first para-electric material 102b and second para-electric material 102c are alternated more than two times (e.g., 6, 10, 12, 20, etc.). In some embodiments, first and second conductive layers 101a/d comprise one or more of: Cu, Al, Co, Au, Ag, W, Graphene, and their alloys.

In some embodiments, the thickness of the first para-electric material 102a (t1) is substantially same as the thickness of the second para-electric material 102c (t2). For example, t1 and t2 are 10 Angstroms (A). In some embodiments, atomic layer deposition (ALD) is used to deposit the first and second para-electric materials. In some embodiments, first para-electric material 102b includes one or more of: HfO₂, ZrO₂, TiO₂, SiO₂, ScO₂, Al₂O₃, ZnO, Sn₂O₃, La₂O₃, nitride, or silicate. In some embodiments, second para-electric material 102b includes one or more of: HfO₂, ZrO₂, TiO₂, SiO₂, ScO₂, Al₂O₃, ZnO, Sn₂O₃, La₂O₃, nitride, or silicate such that the material choice for first para-electric material 102b is different from the material choice of second para-electric material 102b. For example, in some embodiments, first para-electric material 102b is HfO₂ and the second para-electric material 102c is ZnO₂. Other materials for first para-electric material 102b and the second para-electric material 102c include: TiO₂, SiO₂, ScO₂, Al₂O₃, ZnO, Sn₂O₃, La₂O₃, nitride, or silicate.

In some embodiments, the lattice constant of first para-electric material 102b is substantially the same (or equal) to the lattice constant of second para-electric material 102c. In some embodiments, when the thickness of the para-electric materials are the same (or substantially the same), the lattice constant of first para-electric material 102b is substantially different to the lattice constant of second para-electric material 102c. As such, stress can be generated between the crystals of the first and second para-electric materials 102a/c, which changes the crystal properties of the resultant stack of layers. Depending on the materials for 102b/c, a particular temperature may be used to cause or increase the stress between materials 102b so that the stressed crystals behave orthorhombic and thus FE.

In some embodiments, a seed layer (or starting layer) 102e is deposited first and then metal layer 102d, followed by alternating para-electric layers 102c and 102b, and metal layer 102a are deposited. In some embodiments, the seed layer 102e is used to template the conductive layer 102d. In some embodiments, seed layer 102e is deposited in addition to or instead of 102d. In some embodiments, seed layer 102d/e includes one of: Cu, Au, Ag, W, Co, Graphene, Ti, Al, Nb, La, or STO (SrTiO₃).

In some embodiments, when the lattice constant of first para-electric material 102b is substantially the same (or equal) to the lattice constant of second para-electric material 102c, then, one of the first or second para-electric materials can have different thicknesses to generate the stress used to establish the FE properties in the stack of para-electric materials.

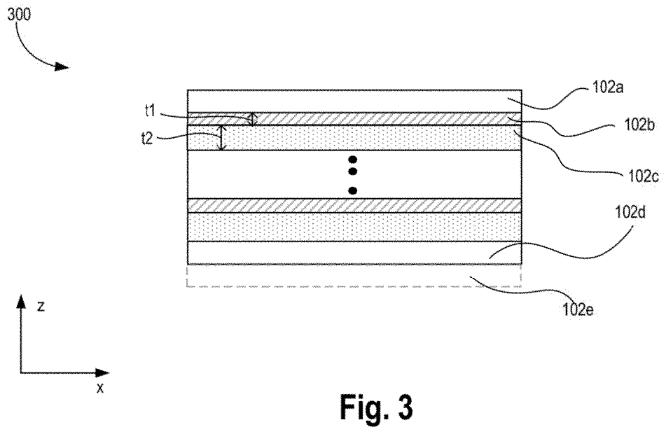

FIG. 3 illustrates a cross-section of an FE-cap 300 comprising alloy of para-electric materials with different thicknesses, according to some embodiments of the disclosure. Compared to FE-cap 200, here second para-electric material layer 102c is thicker than the first para-electric layer 102b (e.g., t2>t1). For example, t2 is 10 A and t2 is 30 A. As such, the second para-electric layer 102c may apply stress to the first para-electric layer 102b to establish the FE properties in the stack of para-electric materials.

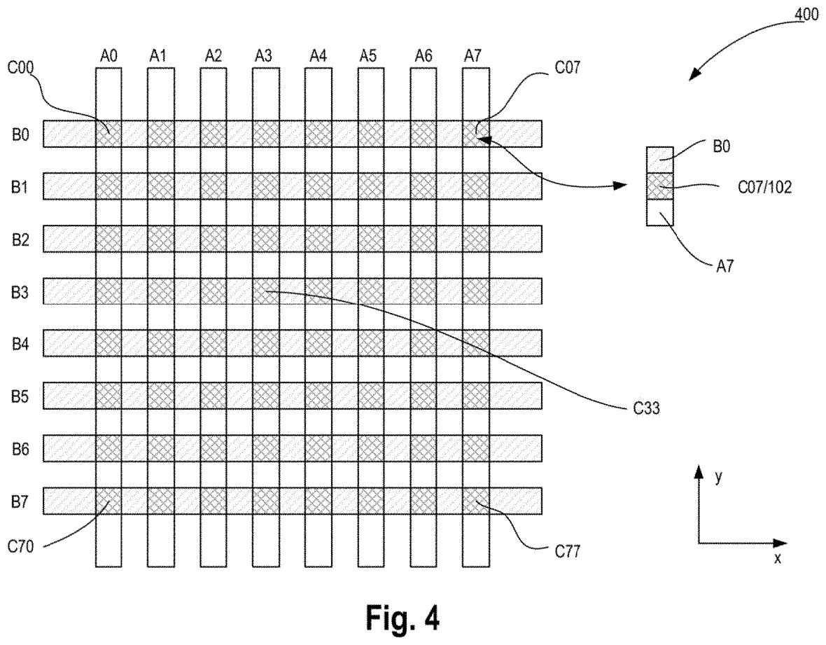

FIG. 4 illustrates an apparatus 400 showing a top down view of distributed metal-insulator-metal (MIM) capacitors comprising FE-caps formed by alloys of para-electric materials, according to some embodiments of the disclosure. Apparatus 400 illustrates a mesh of two layers with an FE-cap formed between the two layers. Here, the first layer is layer B having parallel lines B0 through B7, and the second layer is layer A having parallel lines A0 through A7, where lines A0 through A7 are orthogonal to lines B0 through B7. In this example, 8 lines of layers A and B are shown. However, the disturbed capacitor of various embodiments can be formed with any number of lines of layers A and B.

In some embodiments, the first layer B with lines B0 through B7 is coupled to a power supply, thus forming power supply lines. In some embodiments, the second layer A with lines A0 through A7 is coupled to a ground supply, thus forming ground supply lines. The array of FE-caps here forms a distributed network of parallel capacitors, in accordance with some embodiments. In some embodiments, FE-caps C00 through C77 (not all are label for sake of brevity) are formed between the regions of lines A0 through A7 and B0 through B7. In some embodiments, the FE-caps comprise one of capacitors 102 or 200. In some embodiments, the FE-caps are MIM capacitors.

In some embodiments, the array of FE-caps C00 through C77 is used for charge storage and switching in backend of a computing chip. In some embodiments, the array of FE-caps C00 through C77 is integrated with low voltage logic (e.g., spin logic, eDRAM, etc.) and is used to provide power to it. In some embodiments, the array of supercapacitors C00 through C77 provides power to frontend transistors (e.g., CMOS transistors).

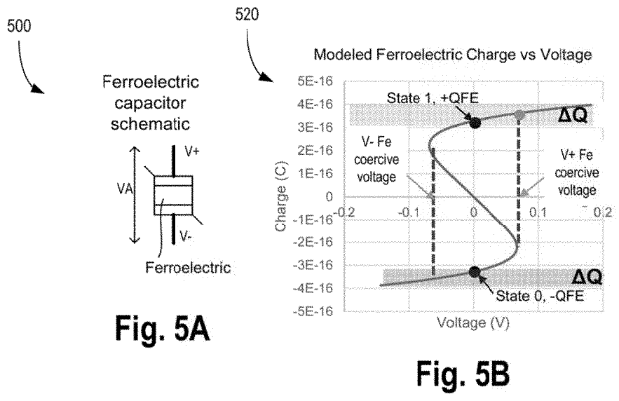

FIG. 5A illustrates a schematic 500 of an FE-Cap comprising an alloy of para-electric materials, according to some embodiments of the disclosure. FIG. 5B illustrates plot 520 showing charge versus voltage function of the FE-Cap comprising an alloy of para-electric materials, and its memory states, according to some embodiments of the disclosure.

Unlike a normal dielectric based capacitor, an FE-cap uses polarization charge to store the memory states, where positive and negative polarization charge indicates state “1” or “0”. To switch an FE-cap, the applied FE-cap voltage VA must be higher than the ferroelectric coercive voltages (which behave as threshold voltages) when driven by a voltage source. For example, VA>V+ for 0 to 1 switching, and VA<V− for 1 to 0 switching. A write driver for ferroelectric is typically based on voltage sources and these voltage sources may induce an imprint voltage on the ferroelectric capacitor due to additional charge deposition, even with VA=V+ for SET, VA=V− for RESET.

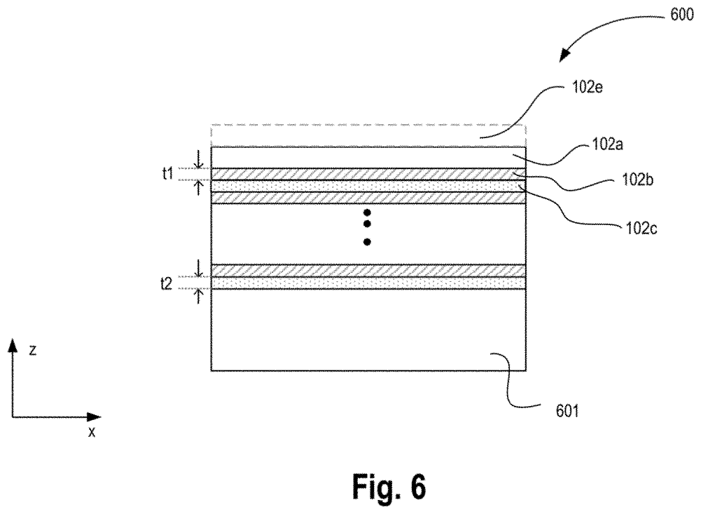

FIG. 6 illustrates a cross-section of FE stack 600 formed on a semiconductor, the FE stack comprising alloy of para-electric materials with same thickness, according to some embodiments of the disclosure. FE stack 600 is similar to FE stack 200 but for replacing second conductive metal 102d with a semiconductor material 601. In this example, seed layer 102e is adjacent to first conductive metal 102a to template the first conductive metal 102a. In some embodiments, seed layer 102e is not used. In some embodiments, semiconductor material 601 is any suitable semi-conductor material. For example, elements from group III-V of the Periodic Table (e.g., silicon, boron, aluminum, gallium, indium, nitrogen, phosphorous, arsenic, antimony, bismuth) can be used for semiconductor material 601.

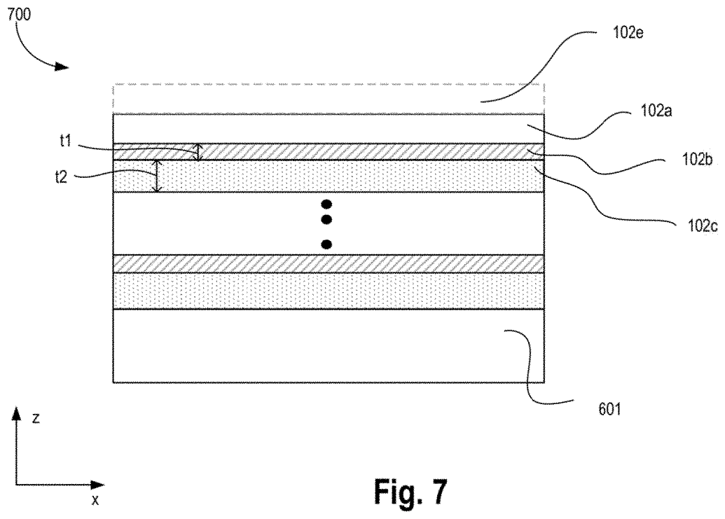

FIG. 7 illustrates a cross-section of an FE stack 700 formed on a semiconductor, the FE stack comprising an alloy of para-electric materials with different thicknesses, according to some embodiments of the disclosure. Compared to FE-cap 600, here, the second para-electric layer 102c is thicker than the first para-electric layer 102b (e.g., t2>t1). For example, t2 is 10 A and t2 is 30 A. As such, second para-electric layer 102c may apply stress to first para-electric layer 102b to establish the FE properties in the stack of para-electric materials.

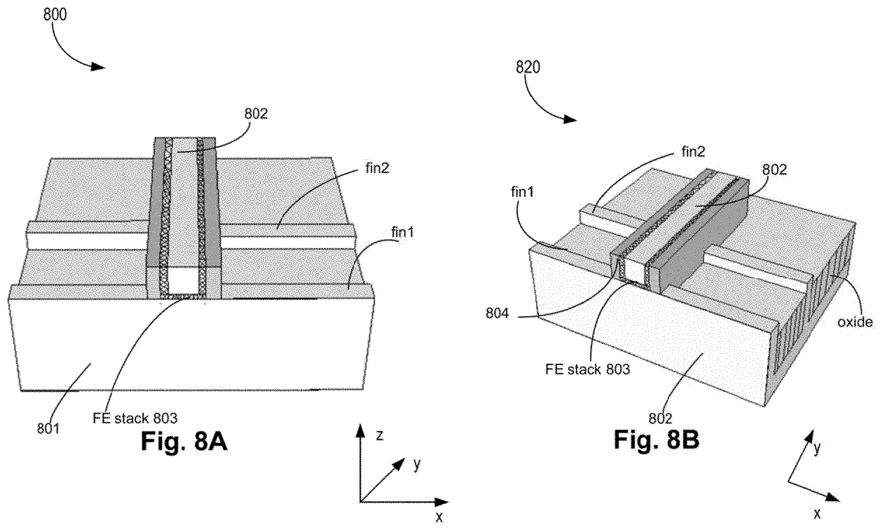

FIGS. 8A-B illustrate 3D views 800 and 820, respectively, of FE field effect transistor (FE-FET) comprising an alloy of para-electric materials, in accordance with some embodiments of the disclosure. 3D views 800 and 820 show two orientations of a same cross-section of the bulk tri-gate transistor. FE-FET cross-section illustrates two fins—fin1 and fin2—active region 801 (e.g., a lightly doped p− region), gate region 802 (e.g., metal gate or high K dielectric gate), FE-cap stack 803 (e.g., 600 or 700, where layer 601 is same as layer or region 801), and spacers 804. The embodiments are not limited to forming FE-FETs using bulk tri-gate transistor, and can be used for forming FE transistors using gate All Around Cylindrical Transistors, Tunneling FET (TFET), Square Wire, or Rectangular Ribbon Transistors, or other devices implementing transistor functionality like carbon nanotubes or spintronic devices.

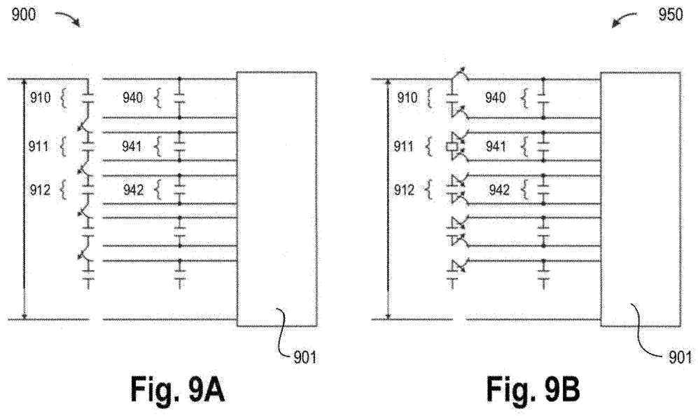

FIGS. 9A-B illustrate apparatuses 900 and 950, respectively, for switch mode power supply during charging and discharging modes, respectively, using FE-caps formed of alloys of para-electric materials, according to some embodiments of the disclosure.

FIG. 9A depicts a charge mode configuration in an SMPS (switch mode power supply) and FIG. 9B depicts a discharge mode configuration in the power supply, in accordance with some embodiments. Elements 940, 941, 942 represent capacitance (e.g., parasitic capacitance) between layers within the chip, in accordance with some embodiments. In some embodiments, capacitors 910, 911, 912 correspond to capacitors C00, C01, C02, etc. of FIG. 4, in accordance with some embodiments. In some embodiments, any of capacitors 910, 911, 912 may correspond to the FE-caps of FIGS. 2-3. In some embodiments, capacitors 940, 941, 942 and onwards are coupled to power and ground lines. In some embodiments, during the SMPS charging mode, capacitors 910, 911, 912 are charged in series. As shown in configuration 950, switching mechanisms (e.g., circuits) may be configured to convert the SMPS from a series to a parallel connection when switching from charge mode to discharge mode, in which capacitors 910, 911, 912 are discharged in parallel.

The series configured charge mode provides for large voltage division and current multiplication, in accordance with some embodiments. For example, a 1 V power supply applied to charge configuration 900 may be divided down over 100 capacitors to provide 10 mV per capacitor. In place of the charging current of, for example, 1 A (Amperes), each of the capacitors supplies a discharge current of 1 A to create the total current of 100 A over the chip. In some embodiments, the parallel configured discharge mode enables ultra-low series resistance as power need not traverse extended paths and instead deploys out-of-plane directly to a device.

In some embodiments, the SMPS includes a charging cycle at, for example, 1 KHz-10 MHz where a bank of capacitors is coupled in series to charge to 1 V (FIG. 9A). In some embodiments, the SMPS includes a discharge cycle at 1 KHz-10 MHz where the capacitors (e.g., each at 10 mV) are discharged in parallel into a device layer. In some embodiments, in order to ensure an uninterrupted power supply, a part of the on-chip capacitors (e.g., C00 through C07) can be in charge mode, while a part of the capacitors (e.g., C10 through C17) can be in discharge mode. Then the SMPS is switched, and charge and discharge modes are reversed.

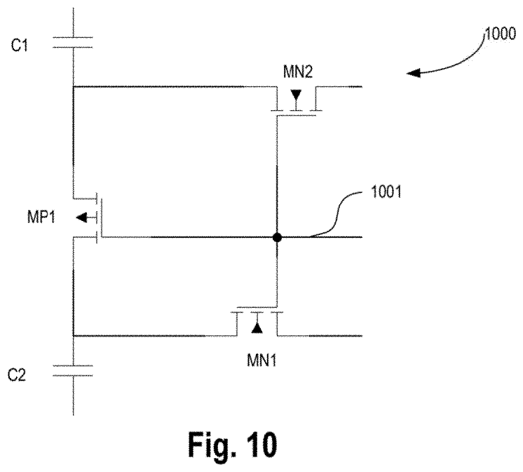

FIG. 10 illustrates a 4-terminal controlled switch for the power plane of FIGS. 9A-B, according to some embodiments of the disclosure. In some embodiments, the 4-terminal controlled switch comprises p-type transistor MP1, n-type transistors MN1 and MN2, and FE-caps C1 and C2 coupled together as shown. In some embodiments, the gate terminals of transistors MP1, MN1, and MN2 are coupled to node 1001 which provides a switching signal. In some embodiments, FE-caps C1 and C2 are according to any one of capacitors 200 or 300. In some embodiments, transistor MP1 is operative during a clock phase and transistors MN1 and MN2 are operative in an opposite SMPS clock phase.

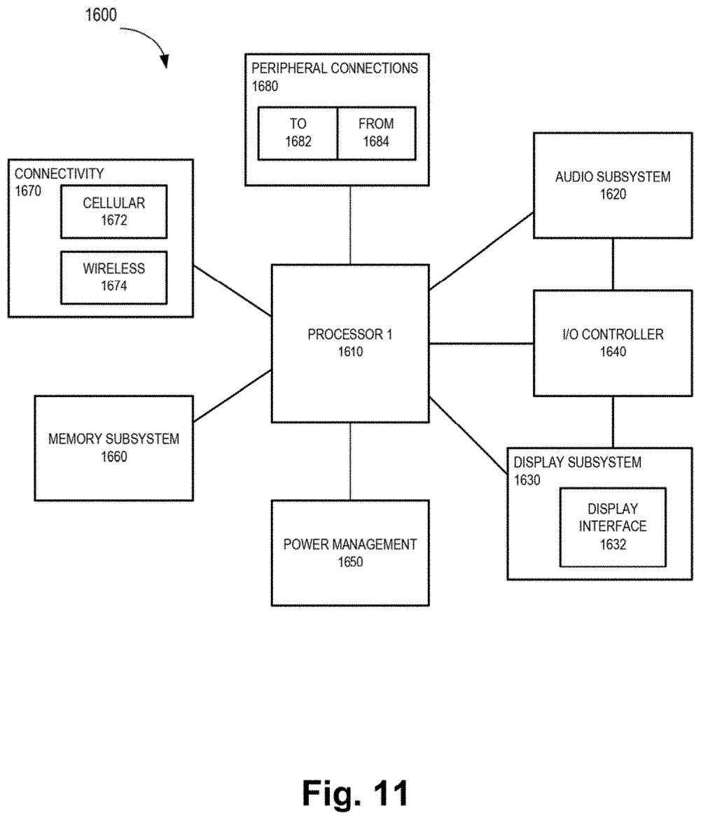

FIG. 11 illustrates a smart device or a computer system or a SoC (System-on-Chip) having an FE-cap comprising alloy of para-electric materials, according to some embodiments. The FE-cap of some embodiments can be used to charge any or all blocks of SoC 2100, in accordance with some embodiments. In some embodiments, the FE-cap is part of a memory array (e.g., 1T1C memory bit-cell). Any block here may use an FE-cap instead of a regular traditional capacitor.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors (BJT PNP/NPN), BiCMOS, CMOS, etc., may be used without departing from the scope of the disclosure.

FIG. 11 illustrates a block diagram of an embodiment of a mobile device in which flat surface interface connectors could be used. In some embodiments, computing device 1600 represents a mobile computing device, such as a computing tablet, a mobile phone or smart-phone, a wireless-enabled e-reader, or other wireless mobile device. It will be understood that certain components are shown generally, and not all components of such a device are shown in computing device 1600. In some embodiments, one or more blocks (even all blocks) may be powered using the supercapacitor.

In some embodiments, computing device 1600 includes first processor 1610 and network interface within 1670 such as a wireless interface so that a system embodiment may be incorporated into a wireless device, for example, cell phone or personal digital assistant. Any of the various blocks of computing device 1600 can have or use the super capacitor of various embodiments.

In some embodiments, processor 1610 (and/or processor 1690) can include one or more physical devices, such as microprocessors, application processors, microcontrollers, programmable logic devices, or other processing means. The processing operations performed by processor 1610 include the execution of an operating platform or operating system on which applications and/or device functions are executed. The processing operations include operations related to I/O (input/output) with a human user or with other devices, operations related to power management, and/or operations related to connecting the computing device 1600 to another device. The processing operations may also include operations related to audio I/O and/or display I/O.

In some embodiments, computing device 1600 includes audio subsystem 1620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1600, or connected to the computing device 1600. In one embodiment, a user interacts with the computing device 1600 by providing audio commands that are received and processed by processor 1610.

In some embodiments, computing device 1600 comprises display subsystem 1630. Display subsystem 1630 represents hardware (e.g., display devices) and software (e.g., drivers) components that provide a visual and/or tactile display for a user to interact with the computing device 1600. Display subsystem 1630 includes display interface 1632, which includes the particular screen or hardware device used to provide a display to a user. In one embodiment, display interface 1632 includes logic separate from processor 1610 to perform at least some processing related to the display. In one embodiment, display subsystem 1630 includes a touch screen (or touch pad) device that provides both output and input to a user.

In some embodiments, computing device 1600 comprises I/O controller 1640. I/O controller 1640 represents hardware devices and software components related to interaction with a user. I/O controller 1640 is operable to manage hardware that is part of audio subsystem 1620 and/or display subsystem 1630. Additionally, I/O controller 1640 illustrates a connection point for additional devices that connect to computing device 1600 through which a user might interact with the system. For example, devices that can be attached to the computing device 1600 might include microphone devices, speaker or stereo systems, video systems or other display devices, keyboard or keypad devices, or other I/O devices for use with specific applications such as card readers or other devices.

As mentioned above, I/O controller 1640 can interact with audio subsystem 1620 and/or display subsystem 1630. For example, input through a microphone or other audio device can provide input or commands for one or more applications or functions of the computing device 1600. Additionally, audio output can be provided instead of, or in addition to display output. In another example, if display subsystem 1630 includes a touch screen, the display device also acts as an input device, which can be at least partially managed by I/O controller 1640. There can also be additional buttons or switches on the computing device 1600 to provide I/O functions managed by I/O controller 1640.

In some embodiments, I/O controller 1640 manages devices such as accelerometers, cameras, light sensors or other environmental sensors, or other hardware that can be included in the computing device 1600. The input can be part of direct user interaction, as well as providing environmental input to the system to influence its operations (such as filtering for noise, adjusting displays for brightness detection, applying a flash for a camera, or other features).

In some embodiments, computing device 1600 includes power management 1650 that manages battery power usage, charging of the battery, and features related to power saving operation. Memory subsystem 1660 includes memory devices for storing information in computing device 1600. Memory can include nonvolatile (state does not change if power to the memory device is interrupted) and/or volatile (state is indeterminate if power to the memory device is interrupted) memory devices. Memory subsystem 1660 can store application data, user data, music, photos, documents, or other data, as well as system data (whether long-term or temporary) related to the execution of the applications and functions of the computing device 1600. In some embodiments, Memory subsystem 1660 includes the scheme of analog in-memory pattern matching with the use of resistive memory elements. In some embodiments, memory subsystem includes the floating-gate transistor, according to some embodiments.

Elements of embodiments are also provided as a machine-readable medium (e.g., memory 1660) for storing the computer-executable instructions (e.g., instructions to implement any other processes discussed herein). The machine-readable medium (e.g., memory 1660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, computing device 1600 comprises connectivity 1670. Connectivity 1670 includes hardware devices (e.g., wireless and/or wired connectors and communication hardware) and software components (e.g., drivers, protocol stacks) to enable the computing device 1600 to communicate with external devices. The computing device 1600 could be separate devices, such as other computing devices, wireless access points or base stations, as well as peripherals such as headsets, printers, or other devices.

Connectivity 1670 can include multiple different types of connectivity. To generalize, the computing device 1600 is illustrated with cellular connectivity 1672 and wireless connectivity 1674. Cellular connectivity 1672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1674 refers to wireless connectivity that is not cellular, and can include personal area networks (such as Bluetooth, Near Field, etc.), local area networks (such as Wi-Fi), and/or wide area networks (such as WiMax), or other wireless communication.

In some embodiments, computing device 1600 comprises peripheral connections 1680. Peripheral connections 1680 include hardware interfaces and connectors, as well as software components (e.g., drivers, protocol stacks) to make peripheral connections. It will be understood that the computing device 1600 could both be a peripheral device (“to” 1682) to other computing devices, as well as have peripheral devices (“from” 1684) connected to it. The computing device 1600 commonly has a “docking” connector to connect to other computing devices for purposes such as managing (e.g., downloading and/or uploading, changing, synchronizing) content on computing device 1600. Additionally, a docking connector can allow computing device 1600 to connect to certain peripherals that allow the computing device 1600 to control content output, for example, to audiovisual or other systems.

In addition to a proprietary docking connector or other proprietary connection hardware, the computing device 1600 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

### EXAMPLE 1

An apparatus comprising: a first layer comprising a metal; a second layer comprising a first para-electric material, the second layer adjacent to the first layer; and a third layer comprising a second para-electric material, the third layer adjacent to the second layer, wherein the first para-electric material is different from the second para-electric material.

### EXAMPLE 2

The apparatus of example 1, wherein the metal of the first layer includes one or more of: Cu, Al, Au, Ag, W, Co, or Graphene.

### EXAMPLE 3

The apparatus according to any one of claim 1 or 2, wherein the first and second para-electric materials include one or more of: Hf, Zr, Ti, Si, Sc, Al, Zn, Sn, La, nitride, or silicate.

### EXAMPLE 4

The apparatus according to any of the preceding examples, wherein the second and third layers are alternated at least two times.

### EXAMPLE 5

The apparatus according to any of the preceding examples, wherein the second and third layers together exhibit a ferroelectric property.

### EXAMPLE 6

The apparatus according to any of the preceding examples, wherein the second layer has a thickness which is substantially same as a thickness of third layer.

### EXAMPLE 7

The apparatus of example 1, wherein the second layer has a thickness which is substantially different than a thickness of third layer.

### EXAMPLE 8

The apparatus according to any one of claims 1, 2, or 4 to 7, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

### EXAMPLE 9

An apparatus comprising: a first set of metal lines extending in a first direction; a second set of metal lines extending in a second direction which is orthogonal to the first direction; and a plurality of vias coupling the first set of metal lines and the second set of metal lines, wherein at least one via of the plurality comprises: alternating layers of first and second layers, wherein the first layer comprises a first para-electric material, the first layer adjacent to the first layer, wherein the second layer comprises a second para-electric material, and wherein the first para-electric material is different from the second para-electric material.

### EXAMPLE 10

The apparatus of example 9, wherein the first and second para-electric materials include one or more of: Hf, Zr, Ti, Si, Sc, Al, Zn, Sn, La, nitride, or silicate.

### EXAMPLE 11

The apparatus of example 9, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

### EXAMPLE 12

The apparatus according to examples 9 or 10, or according to claim 9 or 11, wherein the second layer has a thickness which is substantially same as thickness of third layer.

### EXAMPLE 13

The apparatus according to examples 9 or 10, or according claim 9 or 11, wherein the second layer has a thickness which is substantially different than thickness of third layer.

### EXAMPLE 14

The apparatus of example 9, wherein the alternating layers together exhibit ferroelectric properties.

### EXAMPLE 15

An apparatus comprising: a first layer comprising a metal; a second layer comprising a semiconductor; and alternating layers of a first and second para-electric materials, wherein one of the layers of the alternating layers is adjacent to the first layer, wherein one of the layers of the alternating layers is adjacent to the second layer, and wherein the first and second para-electric materials are different.

### EXAMPLE 16

The apparatus of example 15, wherein the first and second para-electric materials include one or more of: Hf, Zr, Ti, Si, Sc, Al, Zn, Sn, La, nitride, or silicate.

### EXAMPLE 17

The apparatus of claim 15, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

### EXAMPLE 18

The apparatus according to any one of examples 15 to 17, wherein the metal of the first layer includes one or more of: Cu, Al, Au, Ag, W, Co, or Graphene.

### EXAMPLE 19

The apparatus according to any one of examples 15 to 17, wherein the alternating layers together exhibit ferroelectric properties.

### EXAMPLE 20

An apparatus comprising: a first layer comprising a metal; a second layer comprising a metal; and alternating layers of first and second para-electric materials, wherein one of the layers of the alternating layers is adjacent to the first layer, wherein one of the layers of the alternating layers is adjacent to the second layer, and wherein the first and second para-electric materials are different.

### EXAMPLE 21

The apparatus of example 20, wherein the first and second para-electric materials include one or more of: Hf, Zr, Ti, Si, Sc, Al, Zn, Sn, La, nitride, or silicate.

### EXAMPLE 22

The apparatus of claim 20, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

### EXAMPLE 23

The apparatus according to any one of examples 20 to 22, wherein the metal of the first and second layers include one or more of: Cu, Al, Au, Ag, W, Co, or Graphene.

### EXAMPLE 24

The apparatus according to any one of examples 20 to 22, wherein the alternating layers together exhibit ferroelectric properties.

### EXAMPLE 25

A system comprising: a memory; a processor coupled to the memory, the processor including an apparatus according to any one of examples 1 to 8, according to any one of examples 9 to 14, according to any one of examples 15 to 19, or according to any one of examples 10 to 24; and a wireless interface to allow the processor to communicate with another device.

### EXAMPLE 26

A method comprising: forming a first layer comprising a metal; forming a second layer comprising a first para-electric material, the second layer adjacent to the first layer; and forming a third layer comprising a second para-electric material, the third layer adjacent to the second layer, wherein the first para-electric material is different from the second para-electric material.

### EXAMPLE 27

The method of example 26, wherein the metal of the first layer includes one or more of: Cu, Al, Au, Ag, W, Co, or Graphene.

### EXAMPLE 28

The method according to any one of examples 26 to 27, wherein the first and second para-electric materials include one or more of: Hf, Zr, Ti, Si, Sc, Al, Zn, Sn, La, nitride, or silicate.

### EXAMPLE 29

The method according to any one of examples 26 to 28, wherein the second and third layers are alternated at least two times.

### EXAMPLE 30

The method according to any one of examples 26 to 29, wherein the second and third layers together exhibit a ferroelectric property.

### EXAMPLE 31

The method according to any one of examples 26 to 30, wherein the second layer has a thickness which is substantially same as a thickness of the third layer.

### EXAMPLE 32

The method according to any one of examples 26 to 30, wherein the second layer has a thickness which is substantially different than a thickness of the third layer.

### EXAMPLE 33

The method of example 26, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

### EXAMPLE 34

A method comprising: forming a first set of metal lines extending in a first direction; forming a second set of metal lines extending in a second direction which is orthogonal to the first direction; and forming a plurality of vias coupling the first set of metal lines and the second set of metal lines, wherein forming at least one via of the plurality comprises: forming alternating layers of first and second layers, wherein the first layer comprises a first para-electric material, the first layer adjacent to the first layer, wherein the second layer comprises a second para-electric material, and wherein the first para-electric material is different from the second para-electric material.

### EXAMPLE 35

The method of example 34, wherein the first and second para-electric materials include one or more of: Hf, Zr, Ti, Si, Sc, Al, Zn, Sn, La, nitride, or silicate.

### EXAMPLE 36

The method of example 34, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

### EXAMPLE 37

The method according to examples 34 to 35, or according to claim 34 or 36, wherein the second layer has a thickness which is substantially same as thickness of the third layer.

### EXAMPLE 38

The method according to examples 34 to 35, or according to claim 34 or 36, wherein the second layer has a thickness which is substantially different than thickness of the third layer.

### EXAMPLE 39

The method of example 34, wherein the alternating layers together exhibit ferroelectric properties.

### EXAMPLE 40

A method comprising: forming a first layer comprising a metal; forming a second layer comprising a semiconductor; and forming alternating layers of a first and second para-electric materials, wherein one of the layers of the alternating layers is adjacent to the first layer, wherein one of the layers of the alternating layers is adjacent to the second layer, and wherein the first and second para-electric materials are different.

### EXAMPLE 41

The method of example 40, wherein the first and second para-electric materials include one or more of: Hf, Zr, Ti, Si, Sc, Al, Zn, Sn, La, nitride, or silicate.

### EXAMPLE 42

The method of example 40, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

### EXAMPLE 43

The method according to any one of examples 40 to 41, wherein metal of the first layer includes one or more of: Cu, Al, Au, Ag, W, Co, or Graphene.

### EXAMPLE 44

The method according to any one of examples 40 to 41, wherein the alternating layers together exhibit ferroelectric properties.

### EXAMPLE 45

A method comprising: forming a first layer comprising a metal; forming a second layer comprising a metal; and forming alternating layers of a first and second para-electric materials, wherein one of the layers of the alternating layers is adjacent to the first layer, wherein one of the layers of the alternating layers is adjacent to the second layer, and wherein the first and second para-electric materials are different.

### EXAMPLE 46

The method of example 45, wherein the first and second para-electric materials include one or more of: Hf, Zr, Ti, Si, Sc, Al, Zn, Sn, La, nitride, or silicate.

### EXAMPLE 47

The method of example 45, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

### EXAMPLE 48

The method according to any one of examples 45 to 47, wherein metal of the first and second layers include one or more of: Cu, Al, Au, Ag, W, Co, or Graphene.

### EXAMPLE 49

The method according to any one of examples 45 to 47, wherein the alternating layers together exhibit ferroelectric properties.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-25. (canceled)

26. An apparatus comprising:
a first layer comprising a metal;
a second layer comprising a first para-electric material, the second layer adjacent to the first layer; and
a third layer comprising a second para-electric material, the third layer adjacent to the second layer, wherein the first para-electric material is different from the second para-electric material.

27. The apparatus of claim 26, wherein the metal of the first layer includes one or more of: Cu, Al, Au, Ag, W, Co, or Graphene.

28. The apparatus of claim 26, wherein the first and second para-electric materials include one or more of: Hf, Zr, Ti, Si, Sc, Al, Zn, Sn, La, nitride, or silicate.

29. The apparatus of claim 26, wherein the second and third layers are alternated at least two times.

30. The apparatus of claim 26, wherein the second and third layers together exhibit a ferroelectric property.

31. The apparatus of claim 26, wherein the second layer has a thickness which is substantially same as a thickness of third layer.

32. The apparatus of claim 26, wherein the second layer has a thickness which is substantially different than a thickness of third layer.

33. The apparatus of claim 26, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

34. An apparatus comprising:
a first set of metal lines that extend in a first direction;
a second set of metal lines that extend in a second direction which is orthogonal to the first direction; and
a plurality of vias coupling the first set of metal lines and the second set of metal lines, wherein at least one via of the plurality comprises:
alternate layers of first and second layers, wherein the first layer comprises a first para-electric material, the first layer adjacent to the first layer, wherein the second layer comprises a second para-electric material, and wherein the first para-electric material is different from the second para-electric material.

35. The apparatus of claim 34, wherein the first and second para-electric materials include one or more of: Hf, Zr, Ti, Si, Sc, Al, Zn, Sn, La, nitride, or silicate.

36. The apparatus of claim 34, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

37. The apparatus of claim 34, or according to claim 9 or 11, wherein the second layer has a thickness which is substantially same as thickness of third layer.

38. The apparatus of claim 34, wherein the second layer has a thickness which is substantially different than thickness of third layer.

39. The apparatus of claim 34, wherein the alternate layers together exhibit ferroelectric properties.

40. An apparatus comprising:
a first layer comprising a metal;
a second layer comprising a semiconductor; and
alternate layers of a first and second para-electric materials, wherein one of the layers of the alternate layers is adjacent to the first layer, wherein one of the layers of the alternate layers is adjacent to the second layer, and wherein the first and second para-electric materials are different.

41. The apparatus of claim 40, wherein the first and second para-electric materials include one or more of: Hf, Zr, Ti, Si, Sc, Al, Zn, Sn, La, nitride, or silicate.

42. The apparatus of claim 40, wherein the first and second para-electric materials include one or more of: HfO₂, ZrO₂, TiO₂, SiO₂, ScO₂, Al₂O₃, ZnO, Sn₂O₃, La₂O₃, nitride, or silicate.

43. The apparatus of claim 40, wherein the metal of the first layer includes one or more of: Cu, Al, Au, Ag, W, Co, or Graphene.

44. The apparatus of claim 40, wherein the alternate layers together exhibit ferroelectric properties.

45. A system comprising: a memory; a processor coupled to the memory, the processor comprises:
a first layer comprising a metal;
a second layer comprising a first para-electric material, the second layer adjacent to the first layer;
a third layer comprising a second para-electric material, the third layer adjacent to the second layer, wherein the first para-electric material is different from the second para-electric material; and
a wireless interface to allow the processor to communicate with another device.

46. The system of claim 45, wherein the metal of the first layer includes one or more of: Cu, Al, Au, Ag, W, Co, or Graphene.
